(19) United States
(12) Patent Application Publication
(10) Pub. No.: US 2026/0260797 A1
(43) Pub. Date: Sep. 3, 2026

(54) DEVICE FOR MOVEMENT OF AN OPTICAL UNIT, LASER PROCESS HEAD COMPRISING THE DEVICE AND EQUIPMENT COMPRISING THE LASER PROCESS HEAD

(71) Applicant: EL.EN. S.P.A., Calenzano (IT)

(72) Inventors: Giovanni MASOTTI, Calenzano (IT); Angelo BOVE, Calenzano (IT); Francesco LENZI, Calenzano (IT)

(21) Appl. No.: 18/846,725

(22) PCT Filed: Mar. 13, 2023
(86) PCT No.: PCT/IB2023/052400

§ 371 Date: Sep. 13, 2024

(30) Foreign Application Priority Data
Mar. 14, 2022 (IT) 102022000004877

(51) Int. Cl. H01F 7/08; B23K 26/06; B23K 26/064; G01B 11/00; G02B 7/04; H05K 7/20

(52) U.S. Cl. CPC H01F 7/081; B23K 26/0648; B23K 26/0665; G01B 11/002; G02B 7/04; H05K 7/2089

(57) ABSTRACT

The device comprises a body (3) and an optical unit (5), movable with respect to the body (3) along a translation axis (Z). The optical assembly houses the focusing lens (7) with the optical axis (A-A) of the focusing lens (7) parallel to the translation axis (Z) of the optical unit (5). The optical unit comprises a slide (11) which slides along a linear guide system parallel to the translation axis (Z). The device further comprises a magnetic actuator (23) comprising an electromagnetic stator (25) integral with the body (3) and a magnetic piston (27) constrained to the optical unit (5). The magnetic piston (27) is housed in a seat (24) formed in the electromagnetic stator (25) and movable along a motion axis (B-B) parallel to the translation axis (Z) of the optical unit (5).

### TECHNICAL FIELD

The invention relates to a device for the movement of a focusing lens for a laser process head.

### BACKGROUND ART

Laser sources of various kinds find application in many sectors, both medical and industrial. The laser beam generated by a source must be focused on a surface where it is necessary to concentrate the laser energy, for example to perform cutting, welding, marking or other operations. For this purpose, devices for moving a focusing lens, i.e. devices for focusing the laser beam, are provided. When the laser beam and the workpiece move rapidly relative to each other, it may be necessary to make the focusing lens perform rapid focusing movements along the optical axis thereof due to the variation in the distance between the laser head and the surface on which the laser radiation is to be focused.

It would therefore be useful to have a system capable of imposing rapid and precise focusing movements on the focusing lens.

### SUMMARY

According to one aspect, described herein is a device for the movement of a focusing lens, in particular for a laser process head, which allows particularly rapid and precise focusing movements to be obtained.

The device comprises a body and an optical unit, movable with respect to the body along a translation axis. The optical unit is adapted to house the focusing lens, which is mounted with the optical axis parallel to the translation axis of the optical unit. The optical unit comprises a slide which slides along a linear guide system parallel to the translation axis. The device also comprises at least a first magnetic actuator having a first electromagnetic stator integral with the body and a first magnetic piston rigidly constrained to the optical unit. The first magnetic piston is housed in a first seat formed in the first electromagnetic stator and is movable along a first axis of motion parallel to the translation axis of the optical unit. Advantageously, it may be provided that there is no mechanical contact between the piston and the seat formed by the stator and that therefore the movement of the piston in the seat is free and without friction. The reciprocal position between the seat and the piston is obtained by virtue of the rigid connection of the seat to the body of the device and to the rigid connection between the piston and the optical unit and to the fact that the latter is guided by means of shoes along the guide system integral with the body of the device.

To obtain a more balanced thrust, and avoid the generation of torsion moments on the optical unit, in advantageous embodiments the movement device comprises a second magnetic actuator, having a second electromagnetic stator integral with the body and a second magnetic piston constrained to the optical unit. The second magnetic piston is housed in a second seat formed in the second electromagnetic stator and is movable, advantageously without contact with the second seat, along a second axis of motion parallel to the translation axis of the optical unit.

To obtain a balanced thrust, without generating a moment on the optical unit, the first magnetic actuator and the second magnetic actuator are preferably arranged symmetrically with respect to a plane of symmetry of the optical unit, orthogonal to a plane containing the first axis of motion of the first magnetic actuator and of the second axis of motion of the second magnetic actuator.

Advantageously, the guide system comprises a first guide and a second guide, parallel to each other and symmetrical with respect to the plane of symmetry. The slide comprises a first shoe slidingly engaged in the first guide and a second shoe slidingly engaged in the second guide. In advantageous embodiments, at least one of said first shoe and second shoe is connected to the optical unit by an arm having notches adapted to allow flexural deformations of the arm along the direction of the axis joining the centre of the shoes.

In some embodiments, each magnetic piston has a cylindrical configuration with an axis parallel to the direction of movement of the magnetic piston within the seat of the electromagnetic stator and with opposite magnetic poles aligned along the axis of the magnetic piston.

In turn, each electromagnetic stator may comprise a cylindrical part defining the sliding seat of the respective magnetic piston. Associated with the cylindrical wall of each electromagnetic stator is at least a first electro-conductive coil surrounding the respective magnetic piston and coaxial thereto. Preferably, the cylindrical wall of each electromagnetic stator is associated with a pair of electro-conductive coils surrounding the respective magnetic piston and coaxial thereto. The two electro-conductive coils may be connected in series with each other and configured and connected to a source of current so that the same current flows in series in the two electro-conductive coils, clockwise in one of the coils and anti-clockwise in the other, and vice versa. As will become apparent from the following description, a double force generated by the linear magnetic actuator is thus obtained.

Further advantageous features and embodiments of the device for the movement of a focusing lens are described below and are defined in the appended claims, which are intended herein as fully transcribed and forming part of the present description.

According to a further aspect, a laser process head is described comprising a laser source and a movement device as defined above. Also disclosed is an item of equipment comprising a laser head according to claim 21, a workpiece holder for supporting a workpiece to be machined and a reciprocal movement system of the laser head and the workpiece holder.

According to yet another aspect, a linear magnetic actuator is described, comprising an electromagnetic stator with a cylindrical wall, defining a cavity, in which are arranged a first electro-conductive coil and a second electro-conductive coil, wherein said electro-conductive coils surround a magnetic piston slidingly housed in the first electro-conductive coil and in the second electro-conductive coil and coaxial thereto; wherein the first electro-conductive coil and the second electro-conductive coil are connected to one another in series and are wound in opposite directions, so as to generate two opposing electromagnetic fields, which cooperate with the two opposing magnetic poles of the respective magnetic piston. Further features of the magnetic actuator are described below in relation to the use of the magnetic actuator in a focusing device.

According to yet another aspect, an innovative position sensor or device for detecting the reciprocal position of two members movable with respect to each other along a rectilinear trajectory is described.

In practical embodiments, the device or sensor comprises an electromagnetic radiation emitter and an electromagnetic radiation receiver, configured as a position detector. The position detector has a surface sensitive to electromagnetic radiation. The position detector, known per se, is a component which emits two currents, the sum of which is a function of the received electromagnetic radiation intensity, and the difference of which is a function of the position of the electromagnetic radiation spot incident on the sensitive surface. The electromagnetic radiation emitter and the position detector are fixed with respect to each other and applicable to one of the two members, the relative movement whereof, i.e., the relative position whereof, is to be detected. An optical component may be fixed to the other of the two members, so that a relative movement between the first member and the second member causes a relative movement between the optical component and the detector.

The optical component is configured in such a way as to divert the electro-magnetic radiation emitted by the emitter towards the position detector and such that the position of the spot of electromagnetic radiation directed by the optical component onto the sensitive surface of the detector has a position which changes according to the position between the position detector and the optical component and therefore between the two reciprocally moving members.

Advantageously, the optical component may comprise a cylindrical lens having an axis of the cylindrical surface which is inclined with respect to the straight trajectory of relative motion between the first member and the second member in reciprocal motion. The cylindrical lens has a transparent surface facing the emitter and the detector, and an opposing reflective surface, so that in use a beam of electromagnetic radiation emitted by the emitter passes through the cylindrical lens and is reflected towards the detector by the reflective surface. The variable reciprocal position between lens and emitter+position detector defines the variable position of the spot of electromagnetic radiation incident on the sensitive surface of the detector and therefore allows, based on the current signals generated by the latter, the reciprocal position between the first member and second member to be determined.

### BRIEF DESCRIPTION OF THE DRAWINGS

The invention will be better understood by following the description and the accompanying drawings, which illustrate an exemplifying and non-limiting embodiment of the invention. More particularly, the drawings show:

FIG. 1 an isometric view of the device for the movement of an optics for a laser beam or the like in a direction parallel to the optical axis;

FIG. 2 a sectional view of the device of FIG. 1 according to a plane of symmetry containing the optical axis of the focusing lens;

FIG. 3 a section through one of the magnetic actuators of the movement device;

FIG. 4 a front view of the movement device;

FIGS. 5A and 5B an enlargement of detail V of FIG. 4;

FIG. 6 a schematic isometric view of an improved position detector device;

FIG. 7 a plan view of a cylindrical lens of the sensor of FIG. 6;

FIG. 8 a view according to VIII-VIII of FIG. 7;

FIG. 9 a side view of the sensor in an intermediate position;

FIG. 10A a view according to X-X of Fig.;

FIG. 11 a view similar to the view of FIG. 9 in a position shifted to one end of the sensor stroke;

FIG. 12 a view according to XII-XII of FIG. 11;

FIG. 13 a view similar to the view of FIG. 9 in a position shifted to the opposite end;

FIG. 14 a view according to XIV-XIV of FIG. 13; and

FIG. 15 a schematic view of an application of a movement device.

### DETAILED DESCRIPTION

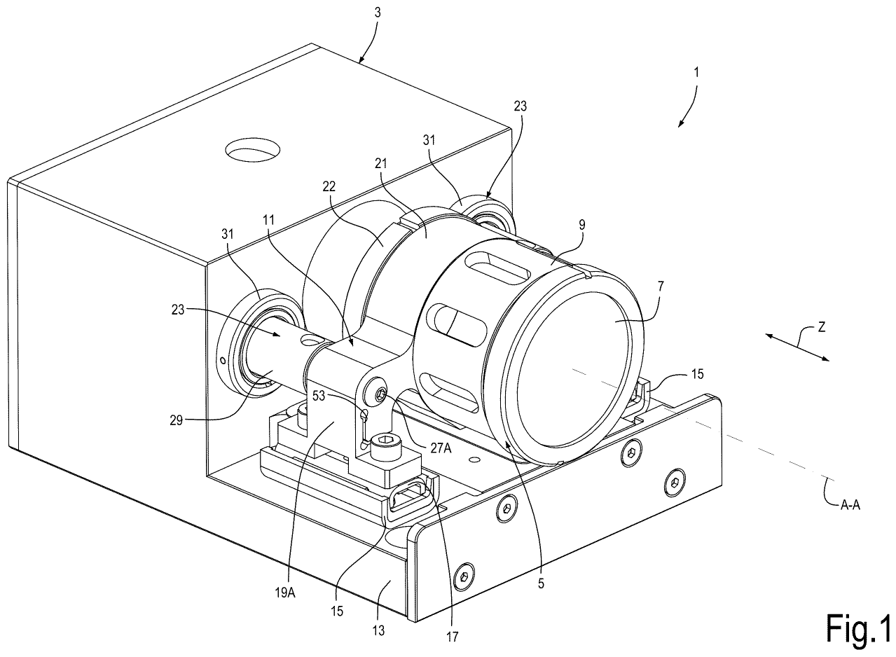

An embodiment of a device for the movement of a focusing lens is illustrated in FIGS. 1 to 5. More specifically, FIG. 1 shows an isometric view of the movement device, indicated as a whole with reference numeral 1.

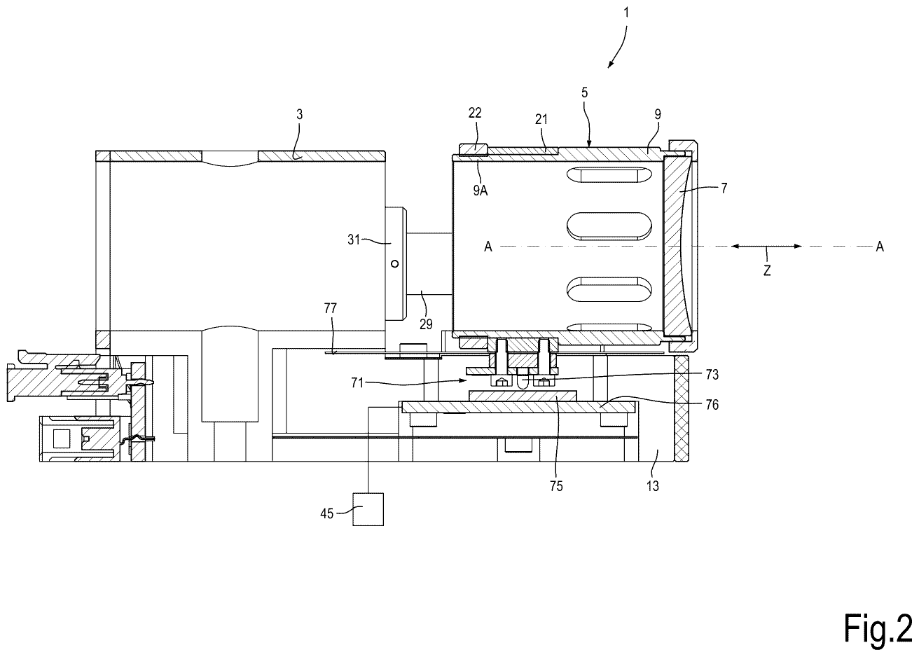

The movement device 1 comprises a body 3, which in use is integral with a laser process head. An optical unit 5 is mounted on the body 3, which is movable with respect to the body 3 according to a translational direction parallel to the optical axis of a focusing lens, mounted on the optical unit 5. The translation axis is indicated with Z. The focusing lens is indicated with reference numeral 7 and can be seen in particular in FIG. 2, which shows a section of the movement device 1 according to a plane of symmetry containing the optical axis A-A of the focusing lens 7. The focusing lens 7 is mounted in a seat formed in a sleeve 9 forming part of the optical unit 5.

The sleeve 9 is integral with a slide or carriage 11, which is movably mounted on the body 3, so as to be able to perform a controlled movement in the direction of the translation axis Z, parallel to the optical axis A-A of the focusing lens 7.

More specifically, the slide 11 is slidingly mounted on a base 13 forming part of the body 3. A guide system for the slide 11 is fixed to the base 13. In the illustrated embodiment, the guide system comprises a first linear guide 15 and a second linear guide 15. The pair of linear guides 15 are parallel to each other and to the translation axis Z. The two linear guides 15 are arranged symmetrically with respect to a plane of symmetry (coinciding with the plane of the section of FIG. 2), which contains the optical axis A-A of the focusing lens 7.

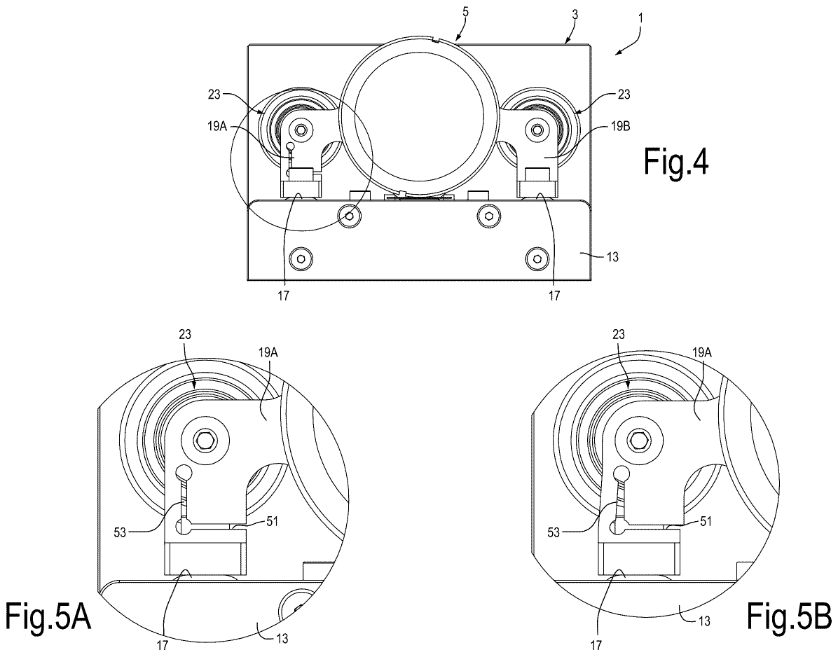

In each guide 15 a respective slide 17 is slidingly engaged, rigidly connected to brackets or arms 19A, 19B, see in particular FIGS. 1 and 4, forming part of the slide 11. In the illustrated embodiment, the brackets 19A, 19B are in turn rigidly connected to a collar 21, which is used to mount the sleeve 9. As can be seen in FIG. 2, in the illustrated embodiment, the sleeve 9 is connected to the collar 21 by means of a threaded ring nut 22, screwed onto a threaded portion 9A of the sleeve 9.

With this configuration, the sleeve 9 and the relative optics contained therein (in particular the focusing lens 7) can be easily replaced without modifying the mechanical parts of the device 1, simply by unscrewing the threaded ring nut 22 and re-placing the sleeve 9.

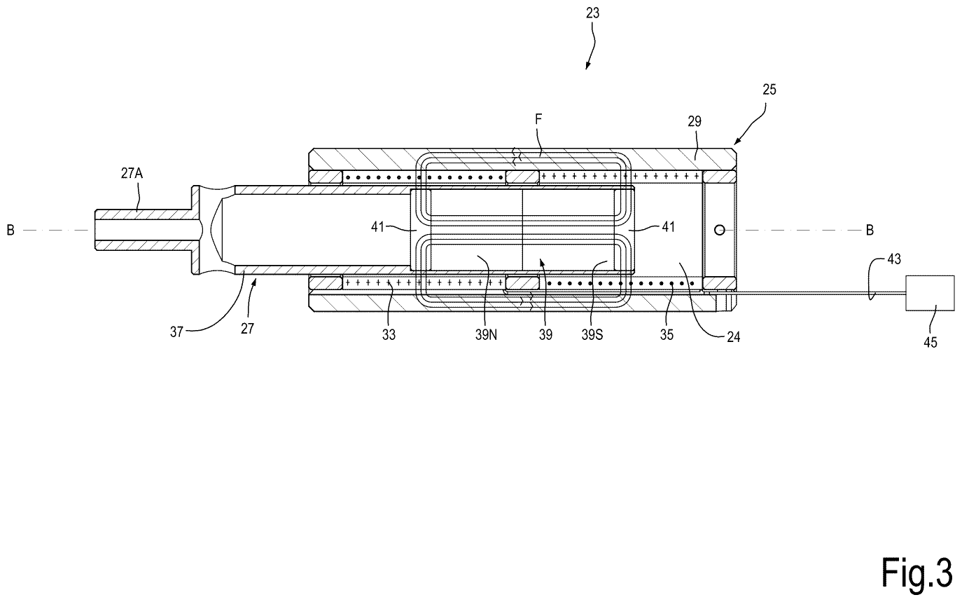

The movement of the optical unit 5 along the translation axis Z represents a focusing movement, since it involves the translation of the focusing lens 7 in the direction of the optical axis A-A of the latter. In the illustrated embodiment, the translation movement along the translation axis Z is imparted by two substantially identical linear magnetic actuators 23, one of which is shown in FIG. 3 in a section along a plane containing the axis of the magnetic actuator 23. The two linear magnetic actuators 23 are arranged symmetrically with respect to the plane of symmetry containing the axis A-A of the focusing lens 7 (i.e. the plane of the section of FIG. 2).

In the illustrated embodiment, each magnetic actuator 23 comprises an electromagnetic stator 25 and a magnetic piston 27, housed movable in the direction of its own axis in a seat 24 formed in the electromagnetic stator 25. The magnetic piston 27 protrudes from one end of the seat 24 to be fixed to the slide 11. In this way, the magnetic piston is rigidly connected to the slide 11 guided by it, so as to be able to move in the respective seat 24 without contact between the magnetic piston 27 and the seat 24.

In the illustrated embodiment, each electromagnetic stator 25 has a substantially cylindrical shape and has a cylindrical wall 29, fixed with a ring nut 31 to the body 3 of the movement device 1. The cylindrical wall 29 is advantageously made of a material with high magnetic permeability.

A system of electro-conductive coils is housed inside the cylindrical wall 29 of each magnetic actuator 23. In the illustrated embodiment, each electromagnetic stator 25 comprises two electro-conductive coils shown in FIG. 3 and indicated with 33 and 35. This configuration allows particular advantages to be obtained in terms of speed and precision of the movement along the translation axis Z of the optical unit 5, described further on.

As schematically indicated in FIG. 3, the electro-conductive coils 33 and 35 are encapsulated in an electrically insulating and thermo-conductive resin, which es-tablishes a thermal bridge with the respective cylindrical wall 29, to which the electro-conductive coils 33, 35 are fixed, so as to increase the heat transfer by conduction from the electro-conductive coils 33, 35 to the cylindrical wall 29. The latter is in turn in intimate thermal contact with the body 3, for example through a thermo-conductive material and/or with the aid of a refrigeration circuit, not shown, to facilitate heat dissipation from the cylindrical wall 29 to the body 3 and from this to the environment, for example by finning (not shown). The arrangement is such as to dissipate the heat generated by the currents circulating in the electro-conductive coils 33, 35 towards the outside.

In the illustrated embodiment, the two electro-conductive coils 33, 35 of each magnetic actuator 23 are connected to each other in series, arranged in sequence along the winding axis and wound in opposite directions, as schematically indicated in FIG. 3. In general, the arrangement of the coils and their connection to the electric current source is such that if the current in the electro-conductive coil 33 flows in a clockwise direction, the current in the electro-conductive coil 35 flows in an anti-clockwise direction, and vice versa.

Each magnetic piston 27 comprises a cylindrical body 37, integral with which is a cylindrical permanent magnet 39, which defines opposite North and South magnetic poles, indicated with 39N and 39S. In rest conditions, the permanent magnet 39 is arranged in a median position between the two electro-conductive coils 33, 35. In the illustrated embodiment, the axial dimensions of the permanent magnet 39 and of the electro-conductive coils 33, 35 are such that in this position the two faces of the cylindrical permanent magnet 39 are approximately halfway along the axial development of the two electro-conductive coils 33, 35, as shown in FIG. 3.

Two discs 41 of material with high magnetic permeability are applied to the two faces of the cylindrical permanent magnet 39, for example of the same material of which the cylindrical wall 29 is made.

The configuration of the cylindrical wall 29 and of the discs 41 is such as to define a magnetic circuit, in which the lines of force F of the permanent magnetic field generated by the permanent magnet 39 are confined.

As mentioned, the two electro-conductive coils 33, 35 of each actuator 23 are connected in series and are accessible from the outside via terminals 43. The terminals 43 of the two pairs of electro-conductive coils 33, 35 of the two magnetic actuators 23 can be connected to the same current source, schematically indicated in FIG. 3 with 45. The connection can be such that the electro-conductive coils 33, 35 of one magnetic actuator 23 are in series or in parallel with the electro-conductive coils 33, 35 of the other magnetic actuator 23. The choice of the type of connection, series or parallel, depends on the driving electronics used. By arranging the electro-conductive coils 33, 35 of the two magnetic actuators 23 in series, a high resistance and limited current are obtained. Conversely, by arranging the electro-conductive coils 33, 35 of the two magnetic actuators 23 in parallel with each other, a lower resistance and a higher current are obtained.

The current generated by the source 45, which flows in the first electro-conductive coil 33 of each magnetic actuator 23 interacts with the radial lines of force F generated by the field of a pole (in the example the pole 39N) of the permanent magnet 39, while the current flowing in the second electro-conductive coil 35 interacts with the radial lines of force F generated by the opposite pole, in the example the south pole 39S. Since the electro-conductive coils 33, 35 are connected in such a way that the currents circulate in opposite directions, they generate on the magnetic piston 27 two equal and concordant forces oriented in the direction of the axis of the cylindrical wall 29 and of the magnetic piston 27, indicated with B-B in FIG. 3, and which constitutes the axis of motion of the actuator 23, parallel to the translation axis Z.

Since the features of the two magnetic actuators 23 are the same, apart from constructive tolerances, by making the same current flow in the electro-conductive coils 33, 35 of the two magnetic actuators 23, the two magnetic pistons 27 generate equal thrust forces on the optical unit 5, except for construction tolerances.

The two magnetic pistons 27 protrude from the electromagnetic stators with ends 27A, by means of which the magnetic pistons are fixed to the slide 11, and more exactly to the arms 19A, 19B. In advantageous embodiments, the attachment points of the two magnetic pistons 27 to the slide 11 are located at the two ends of a straight line segment, the mid-point whereof is substantially located in the centre of mass of the movable optical unit 5. This geometry is aimed at minimizing the generation of twist-ing moments on the optical unit 5 during the application of the thrust forces generated by the magnetic actuators 23.

By applying the same current to the two magnetic actuators 23, the optical unit 5 is urged by a resultant force parallel to the axis Z (and to the optical axis A-A of the focusing lens 7), passing through the centre of mass of the optical unit and no lateral forces are generated which could move, deform, or cause the optical unit 5 to vibrate laterally.

As a further improvement, measures are provided to limit the effect of any thermal gradients induced by the heating due to the circulation of the currents in the electro-conductive coils 33, 35 of the magnetic actuators 23, and consequent differential expansions in the various areas of the device 1.

To this end, as can be seen in particular in FIGS. 4, 5A, 5B, one of the arms 19A, 19B (in the example the arm 19A) has notches 51, 53 which allow the arm to deform following any differential thermal expansion, reducing the thermally induced stresses to a minimum. The thermal expansion and consequent deformation of the arm 19A can be appreciated from the comparison between FIG. 5A (condition without thermal expansion) and FIG. 5B, in which the notches 51, 53 allow an elastic flexural deformation of the arm 19A in the direction parallel to the line joining the two shoes 17. The notches 51, 53 are such as not to reduce the stiffness of the arm 19A in the direction Z, along which there must be no deformations, either thermally induced or induced by the inertia forces generated by the motion in the direction Z, so as to keep the optical axis A-A of the focusing lens 7 in the correct position in all operating conditions of the movement device 1.

To detect the exact position of the optical unit 5 with respect to the base 13, and therefore with the body 3, in some embodiments a device is provided for detecting the relative position of the optical unit 5 with respect to the body 3, hereinafter also referred to as “sensor” and collectively indicated with 71 (FIG. 2). In the illustrated embodiment, the sensor 71 comprises an electromagnetic radiation emitter, for example a LED 73, typically operating in the near infrared (IR), which generates a light beam. The light beam is detected by a detector 75, for example a linear position detector, which can be mounted on a board 76. The detector 75 is integral with the base 13 of the body 3, while the emitter 73 is integral with the optical unit 5. In the illustrated embodiment, the sensor 71 is placed in an intermediate position between the two linear guides 15, with the emitter fixed on the part of the optical unit 5 facing the base 13 and towards the linear position detector 75, which is mounted in the base 13. A plate 77 integral with the optical unit 5 shields the linear position detector 75 from external radiation.

The emitter 73 can be supplied with constant current to generate a constant luminous flux incident on the surface of the linear position detector 75. At the output of the linear position detector 75, two photo-currents are generated which are proportional to the luminous flux generated by the emitter 73, the intensities of which depend on the relative position between the emitter 73 and the linear position detector 75. By combining the sum and the difference of the two photo-currents it is possible to determine with high precision and resolution the relative position of the centroid of the light spot generated by the emitter 73 which strikes the sensitive surface of the linear position detector 75, with respect to the centre of said surface, and therefore ultimately the position of the slide 11 with respect to the base 13 of the body 3.

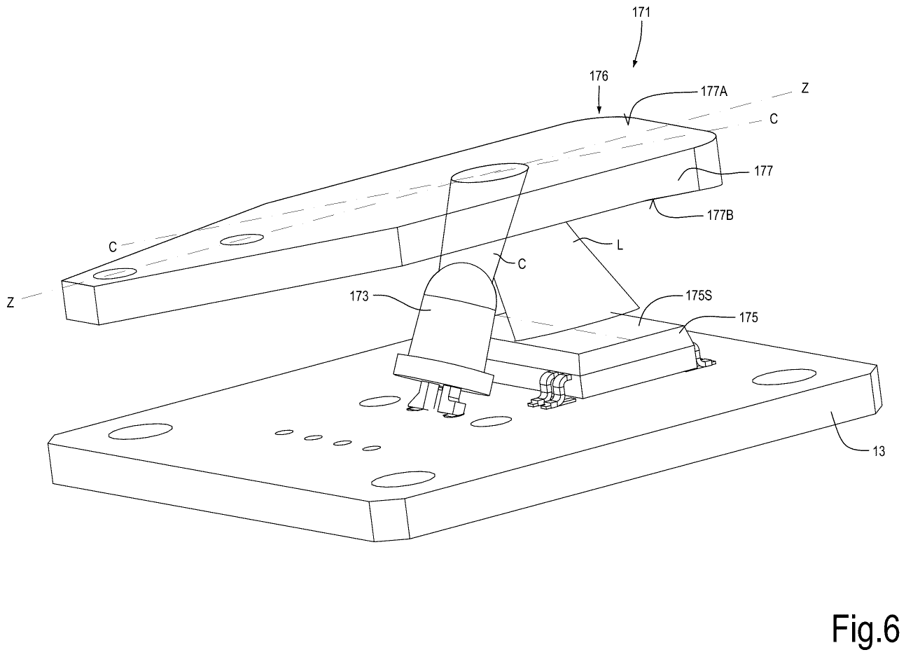

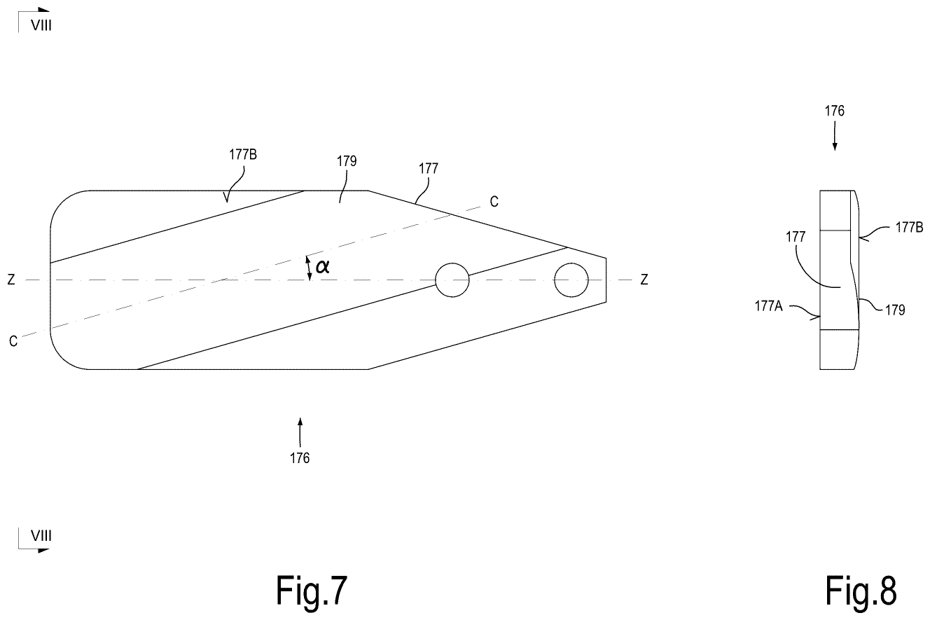

An improved embodiment of the position sensor is illustrated in FIGS. 6 to 14. The sensor, indicated with 171, can be used in the device described herein, but can find advantageous use in any device in which it is necessary to detect the position of a member which moves along a translation trajectory.

The sensor 171 comprises an electromagnetic radiation emitter 173, similar to the emitter 73, and a position detector 175, similar to the detector 75. In the sensor 171, the emitter 73 and the detector 175 are stationary with respect to each other. When used in the device 1, the emitter 173 and the detector 175 can both be integral with the base 13. To detect a relative displacement between the base 13 and the optical unit 5 (or more generally between two components provided with a relative movement with respect to each other), the sensor 175 is provided with a cylindrical lens 177, which is integral with the optical unit 5.

The cylindrical lens 177 is formed on an optical component 176 having a preferably flat surface 177A facing away from the emitter 173 and the detector 175 and coated with a reflective material. The surface 177A can be metallized, for instance. The optical component also has a surface 177B facing the emitter 173 and the detector 175 and provided with a cylindrical portion.

The cylindrical portion of the surface 177B is indicated with 179 and forms the actual cylindrical lens. The axis of the cylindrical lens 177, i.e., the axis of the cylindrical surface 179, is indicated with C-C.

The component forming the cylindrical lens 177 is mounted on the optical unit 5 in such a way that the axis C-C of the cylindrical lens 177 is inclined by an angle α with respect to the translation direction Z of the optical unit 5. The direction Z cor-responds to the median axis of the optical element which configures the cylindrical lens 177.

The beam of electromagnetic radiation emitted by the emitter 173, for example a near infrared LED, forms a very narrow cone C which illuminates the cylindrical surface 179 of the cylindrical lens 177, passes through the cylindrical lens 177 and is reflected by the metallized flat surface 177A. The reflected beam passes through the cylindrical lens again and exits the surface 179 in the form of a blade of light L which strikes a sensitive surface 175S of the position detector 175. The detection axis of the detector 175 is perpendicular to the translation axis Z of the optical unit 5. In substance, the detection axis of the detector 175 is the axis along which the spot of the electro-magnetic radiation, generated by the emitter 173 and reflected by the optical component 176 towards the detector 175, moves.

The sensitive surface 175S of the position detector 175 is preferably flat and preferably parallel to the reflective surface 177A of the optical component 176.

The electromagnetic radiation reflected by the cylindrical lens 177 and incident on the sensitive surface 175S of the detector 175 is an ellipsoidal-shaped spot having the major axis perpendicular to the axis C-C of the cylinder of the cylindrical lens 177.

As a result of the inclination α of the axis C-C with respect to the direction of motion Z, the displacement of the cylindrical lens 177 integrally with the carriage 11 and with the optical unit 5 along the translation axis Z causes the axis of the blade of reflected light to tilt, i.e. the major axis of the ellipse projected onto the sensitive surface 175S, proportionally to the movement of the carriage 11 and of the optical unit 5. In other words, the centroid of the ellipsoidal spot incident on the sensitive surface 175S of the detector 175 moves along the axis of the sensitive surface in proportion to the movement of the carriage along the translation axis.

The axis of the sensitive surface, i.e. the detection axis, is in substance the straight line on the sensitive surface, along which the displacement of the centroid of the elliptical spot incident on the sensitive surface 175S of the detector 175 is detected.

The emitter 173 is supplied with constant current and generates a constant luminous flux incident on the sensitive surface 175S of the detector 175. At the output of the detector 175, 2 photo-currents (Ia and Ib) are generated, the sum of which is proportional to the luminous flux generated by the emitter 173, and the difference of which is proportional to the position of the centroid of the spot incident on the sensitive surface 175S with respect to the centre of the sensitive surface and therefore proportional to the position of the centroid of the spot along the axis of the sensitive surface 175S.

Since the detection axis of the sensitive surface 175S is orthogonal, i.e. oriented at 90°, with respect to the direction of relative motion between the optical unit 5 and the emitter 173, i.e. to the Z axis, the difference between the two photo-currents is a function of the relative position of the spot (and more specifically of the centroid thereof) along the direction orthogonal to the axis Z. The position of the spot along the detection axis of the sensitive surface 175S, which is detected based on the difference between the two photo-currents, is a function of the relative position between the optical unit 5 and the stationary structure (body 3), wherewith the emitter 173 is integral.

By combining the sum and the difference of the two photo-currents it is possible to determine with extremely high precision and resolution the relative position of the centroid of the spot which strikes the sensitive surface 175S with respect to the centre of the sensitive surface 175 and definitively the position of the carriage 11 and of the optical unit 5 along the translation axis Z.

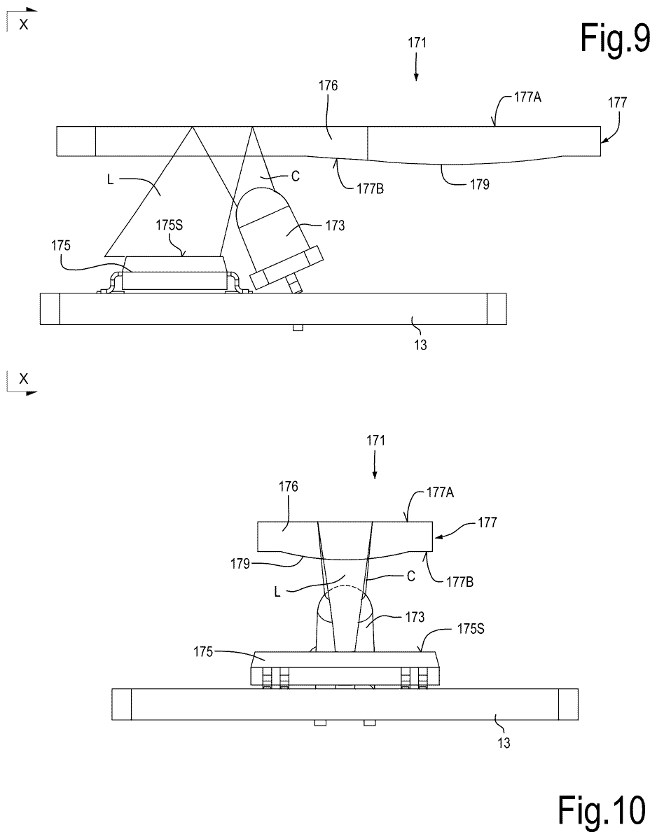

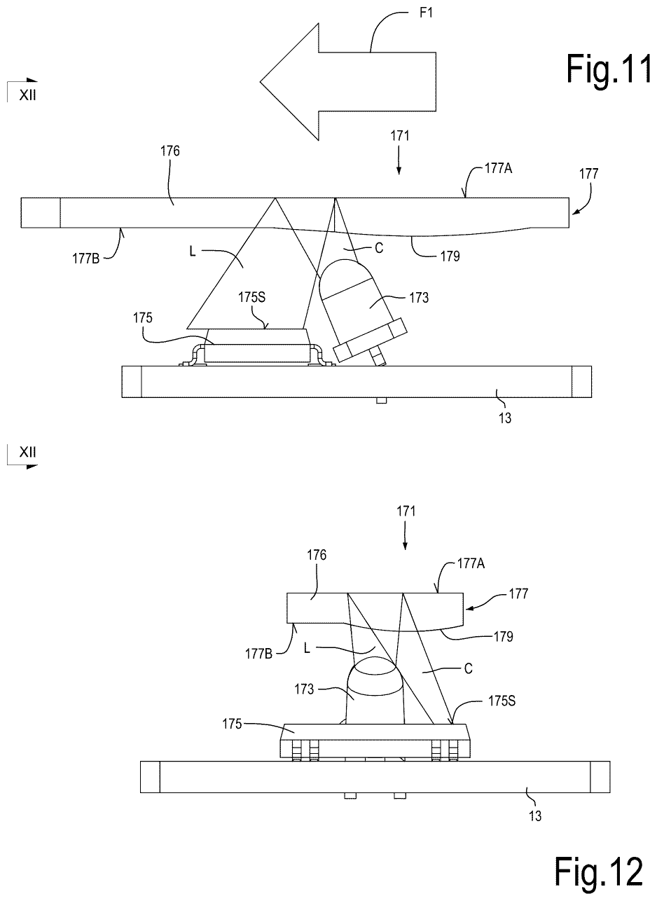

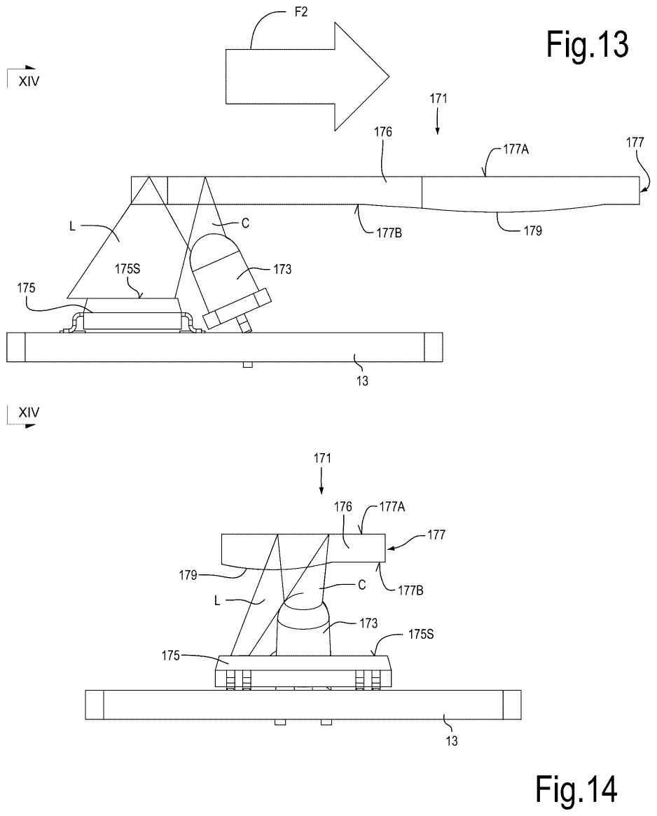

The movements described above of the blade L of electromagnetic radiation reflected and outgoing from the cylindrical lens 177 and of the centroid of the electro-magnetic radiation spot formed by the blade L of electromagnetic radiation on the sensitive surface 175S of the detector 175 are visually represented in FIGS. 9 to 14. In particular, FIGS. 9 and 10 show the position of the conical beam C and of the blade L when the cylindrical lens 177 and therefore the optical unit 5 are in a central position. FIGS. 11 and 12 show the position of the blade L of electromagnetic radiation when the cylindrical lens 177 (and therefore the optical unit 5 integral with it) are moved completely to the left (in the drawing) as represented by the arrow F1. FIGS. 13 and 14 show the position of the blade L of electromagnetic radiation when the cylindrical lens 177 (and therefore the optical unit 5 integral with it) are moved completely to the right (in the drawing) as represented by the arrow F2.

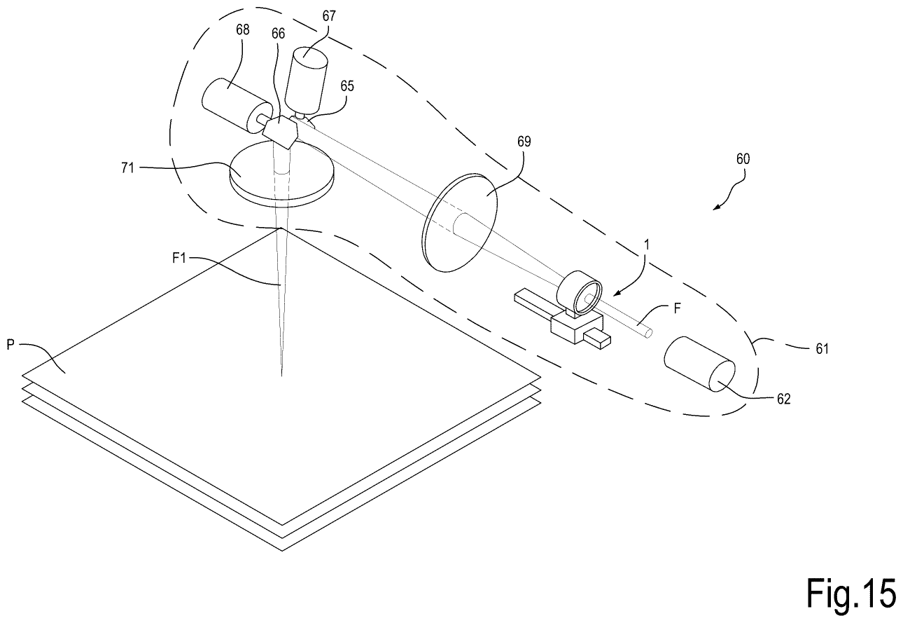

FIG. 15 schematically shows an example of use of a movement device 1 of the type described above. FIG. 15 shows an apparatus 60 comprising a laser head 61 comprising, or associated with, a laser source 62. F indicates the laser beam generated by the laser source 62. In the embodiment schematically illustrated in FIG. 15 the laser source is aligned with the movement device 1, comprising the optics 7. The laser beam F which emerges from the optics 7 is controlled by one or two deflection mirrors, or scanning mirrors 65, 66, which can pivot around two axes which are not parallel to each other, for example orthogonal to one another, under the control of two actuators 67, 68, for example two galvanometers. A fixed focusing lens 69 is placed between the scanning mirrors and the movement device 1. The laser beam F1 deflected by the deflection mirrors 65, 66 passes through a lens 71 and affects an object to be worked, for example to be engraved, marked or cut, schematically indicated with P.

Having described some embodiments of the movement device and its components, specific features of the object described herein are summarized in the following clauses:
1. A device (1) for the movement of a focusing lens (7) along an optical axis (A-A) of the focusing lens (7), the device comprising:
a body (3);
an optical unit (5), movable with respect to the body (3) along a translation axis (Z) and adapted to house the focusing lens (7) with the optical axis (A-A) of the focusing lens (7) parallel to the translation axis (Z) of the optical unit (5); wherein the optical unit comprising a slide (11) sliding along a linear guide system parallel to the translation axis (Z);
at least a first magnetic actuator (23) comprising a first electromagnetic stator (25) integral with the body (3) and a first magnetic piston (27) constrained to the optical unit (5); wherein the first magnetic piston (27) is housed in a first seat (24) formed in the first electromagnetic stator (25) and movable along a first axis of motion (B-B) parallel to the translation axis (Z) of the optical unit (5).
2. The movement device (1) of clause 1, comprising a second magnetic actuator (23), comprising a second electromagnetic stator (25) integral with the body (3) and a second magnetic piston (27) constrained to the optical unit (5); wherein the second magnetic piston (27) is housed in a second seat (24) formed in the second electromagnetic stator (25) and movable along a second axis of motion (B-B) parallel to the translation axis (Z) of the optical unit (5).
3. The movement device (2) of clause 2, wherein the first magnetic actuator (23) and the second magnetic actuator (23) are arranged symmetrically with respect to a plane of symmetry of the optical unit (5), orthogonal to a plane containing the first axis of motion (B-B) of the first magnetic actuator (23) and of the second axis of motion (B-B) of the second magnetic actuator (23).
4. The movement device (1) of clause 3, wherein the guide system comprises a first guide (15) and a second guide (15), parallel to one another and symmetrical with respect to the plane of symmetry; and wherein the slide (11) comprises a first shoe (17) slidingly engaged in the first guide (15) and a second shoe (17) slidingly engaged in the second guide (15).
5. The movement device (1) of clause 4, wherein at least one of said first shoe (17) and second shoe (17) is connected to the optical unit (5) by an arm (19A) with notches (51, 53) adapted to allow flexional deformations of the arm in a direction connecting the centres of the first shoe (17) and the second shoe (17).
6. The movement device (1) of one or more of the previous clauses, wherein each magnetic piston (27) has a cylindrical shape with an axis parallel to the direction of movement of the magnetic piston and with opposing magnetic poles (39N, 39S) aligned along the axis of the magnetic piston (27).
7. The movement device (1) of one or more of the previous clauses, wherein each electromagnetic stator (25) comprises a cylindrical wall defining a cavity, within which the respective magnetic piston is slidingly housed, and wherein the cylindrical wall (29) of each electromagnetic stator (25) is associated with at least a first electro-conductive coil (33; 35) surrounding the respective magnetic piston (27) and coaxial thereto.
8. The movement device (1) of clause 7, wherein the cylindrical wall (29) of each electromagnetic stator (25) is associated with a second electro-conductive coil (35; 33) surrounding the respective magnetic piston (27) and coaxial therewith;
9. The movement device (1) of clause 8, wherein the first electro-conductive coil (33; 35) and the second electro-conductive coil (35; 33) are connected to each other in series.
10. The movement device (1) of clause 8 or 9, wherein the first electro-conductive coil (33; 35) and the second electro-conductive coil (35; 33) of each magnetic actuator (23) are wound and connectable to a source of current, so as to generate two opposite electromagnetic fields, which cooperate with the two opposite magnetic poles (39N, 39S) of the respective magnetic piston (27).
11. The movement device (1) of clause 8, 9 or 10, wherein the electro-conductive coils (33; 35) of the first magnetic actuator (23) and of the second magnetic actuator (23) are connected to one another in series or in parallel to two poles connecting to an electrical power source.
12. The movement device (1) of one or more of clauses 8 to 11, wherein the cylindrical wall (29) of each electromagnetic stator (25) is made from a material with high magnetic permeability and surrounds the respective electromagnetic coil or coils (33; 35) associated therewith.
13. The movement device (1) of clause 12, wherein each magnetic piston (27) comprises a cylindrical body featuring the two opposing magnetic poles (39S, 39N), and two opposing discs (41) with high magnetic permeability associated with two opposing ends of the cylindrical body; and wherein the cylindrical wall (29) in high magnetic permeability material and the two discs (41) with high magnetic permeability form a magnetic circuit in the respective magnetic actuator (23).
14. The movement device (1) of one or more of clauses 2 to 13, wherein the first magnetic piston (29) and the second magnetic piston (29) are mechanically connected to the optical unit (5) at two points located on the ends of a segment, the mid-point whereof coincides with the centre of mass of the optical unit (5).
15. The movement device (1) of one or more of the previous clauses, comprising a position sensor (71; 171), adapted to detect the relative position of the optical unit (5) with respect to the body (3).
16. The movement device (1) of clause 15, wherein the position sensor (71; 171) comprises an electromagnetic radiation emitter (73; 173) and a linear position detector (75; 175), having a sensitive surface adapted to receive an electromag-netic radiation emitted by the emitter (73; 173); wherein the position detector (75; 175) is adapted to generate a signal which is a function of the position of a spot of electro-magnetic radiation generated by the emitter (73; 173) on the sensitive surface of the position detector.
17. The movement device (1) of clause 16, wherein the linear position detector is associated with a shield integral with the optical unit and adapted to shield external radiation.
18. The movement device (1) of clause 16 or 17, wherein the emitter (73) is integral with the optical unit (5) and wherein the position detector is integral with the body (3); and wherein the movement of the optical unit (5) along the translation axis (Z) causes a displacement of the electromagnetic radiation spot on the sensitive surface of the position detector (75) in a direction parallel to the direction of the translation axis (Z).
19. The movement device (1) of clause 16 or 17, wherein the electro-magnetic radiation emitter (173) and the position detector (175) are fixed with respect to one another and are integral with one of said body (3) and said optical unit (5); the position sensor comprises a cylindrical lens (177), movable integrally with the other of said body (3) and said optical unit (5), so that a relative movement between the optical unit (5) and the body (3) causes a relative movement between the cylindrical lens (177) and the detector (175); wherein the cylindrical lens (177) has an axis (C-C) inclined with respect to the direction of translation (Z) of the optical unit (5); wherein the cylindrical lens has a transparent surface (177B) turned towards the emitter (173) and the detector (175), and an opposing reflective surface (177A), so that a beam of electromagnetic radiation emitted by the emitter (173) passes through the cylindrical lens and is reflected towards the detector (175), forming a spot on the sensitive surface (175S) of the detector, the position of said spot being a function of the mutual position between the cylindrical lens (177) and detector (175).
20. The movement device (1) of one or more of the previous clauses, wherein each magnetic actuator (23) comprises a system for dissipation of the heat generated by the electro-conductive coils, preferably comprising one of: a thermic coupling between each electro-conductive coil and the respective cylindrical wall (29) of the electromagnetic stator (25); a circuit for the transfer of heat from the cylindrical wall (29) of the electromagnetic stator (25) to the body (3), or both.
21. The movement device (1) of one or more of the previous clauses, wherein the optical unit (5) comprises a sleeve (9) in which the focusing lens (7) is housed, the sleeve preferably being interchangeable; and wherein the sleeve is preferably fixed in a manner allowing it to be removed from the slide (11), for example by means of a threaded ring nut (22).
22. A laser head comprising a laser source and a movement device according to one or more of the previous clauses.
23. An item of equipment comprising a laser head according to clause 21, and a system for reciprocal movement between the laser beam and a piece to be worked on using the laser beam.
24. A linear magnetic actuator, comprising an electromagnetic stator with a cylindrical wall, defining a cavity, in which are arranged a first electro-conductive coil and a second electro-conductive coil, wherein said electro-conductive coils surround a magnetic piston slidingly housed in the first electro-conductive coil and in the second electro-conductive coil and coaxial thereto; wherein the first electro-conductive coil and the second electro-conductive coil are connected to one another in series and are wound in opposite directions, so as to generate two opposing electro-magnetic fields, which cooperate with the two opposing magnetic poles of the respective magnetic piston.
25. The actuator of clause 24, wherein: the cylindrical wall of the electromagnetic stator is made from a material with high magnetic permeability; the magnetic piston comprises a cylindrical body featuring the two opposing magnetic poles, and two opposing discs with high magnetic permeability associated with two opposing ends of the cylindrical body; and the cylindrical wall made of a material with high magnetic permeability and the two discs with high magnetic permeability form a magnetic circuit.
26. A device (171) for detecting the reciprocal position of a first member and a second member moving relative to each other along a straight trajectory; the device comprising:
an electromagnetic radiation emitter (173);
a position detector (175), with a surface sensitive (175S) to electromagnetic radiation; wherein the electromagnetic radiation emitter (173) and the position detector (175) are fixed with respect to each other and applicable to one of said first member (3) and second member (5);
an optical component (176), applicable to the other of said first member (3) and second member (5), so that a relative movement between the first member (3) and the second member (5) causes a relative movement between the optical component (177) and the detector (175);
wherein the optical component is configured in such a way as to divert the electromag-netic radiation emitted by the emitter towards the position detector and such that the position of the spot of electromagnetic radiation directed by the optical component onto the sensitive surface of the detector has a position which changes according to the position between the position detector and the optical component and therefore between the two reciprocally moving members.
27. The device of clause 26, wherein: the optical component comprises a cylindrical lens (177) with an axis (C-C) inclined with respect to the straight trajectory of relative movement between the first member (3) and the second member (5); wherein the cylindrical lens (177) has a transparent surface (177B) facing the emitter (173) and the detector (175), and an opposing reflective surface (177A), so that in use a beam of electromagnetic radiation emitted by the emitter (173) passes through the cylindrical lens and is reflected towards the detector (175) by the reflective surface (177A), forming a spot on the sensitive surface (175S) of the detector, the position whereof depends on the reciprocal position between the cylindrical lens (177) and the detector (175) and which moves along an axis of the sensitive surface in a manner proportional to the relative movement between the first member (3) and the second member (5).
28. The device of clause 27, wherein the axis of the sensitive surface (172S) is orthogonal to the rectilinear trajectory (Z) of the relative movement between the first member (3) and the second member (5).
29. The device of any one of clauses 26 to 28, wherein the detector is configured such as to generate two photo-currents, the sum whereof is proportional to the luminous flux of generated by the emitter (173), and the difference whereof is proportional to the position of the centroid of the spot incident on the sensitive surface (175S) with respect to the center of the sensitive surface (175S).
30. The device of any one of claims 26 to 29, wherein the reflective surface is a flat surface, preferably parallel to the sensitive surface of the detector.
31. A device (171) for detecting the respective position of a first member and a second member movable one with respect to the other along a rectilinear trajectory; the device comprising:
an electromagnetic radiation emitter (173);
a position detector (175), having a surface (175S) sensitive to the electro-magnetic radiation; wherein the electromagnetic radiation emitter (173) and the position detector (175) are fixed one with respect to the other and applicable to one of said first member (3) and second member (5);
an optical component (176), applicable to the other of said first member (3) and second member (5), such that a relative movement between the first member (3) and the second member (5) causes a relative movement between the optical component (177) and the detector (175);
   wherein the optical component comprises a cylindrical lens (177) with an axis (C-C) which is inclined with respect to the rectilinear trajectory (Z) of the relative motion between the first member (3) and the second member (5); wherein the cylindrical lens (177) has a transparent surface (177B) facing the emitter (173) and the detector (175), and an opposing reflecting surface (177A), such that in use a beam of electromagnetic radiation emitted by the emitter (173) passes through the cylindrical lens and is reflected towards the detector (175) by the reflective surface (177A), forming on the sensitive surface (175S) of the detector a spot, the position whereof is a function of the relative position of the cylindrical lens (177) and the detector (175) and moves along the axis of the sensitive surface proportionally to the relative displacement of the first member (3) and the second member (5); and wherein the detector is configures such as to generate two photo-currents, the sum whereof is proportional to the luminous flux generated by the emitter (173), and the difference whereof is proportional to the position of the centroid of the spot incident on the sensitive surface (175S) with respect to the center of the sensitive surface (175S).

1. A device for the movement of a focusing lens along an optical axis of the focusing lens, the device comprising:
a body;
an optical unit movable with respect to the body along a translation axis and adapted to house the focusing lens with the optical axis of the focusing lens parallel to the translation axis of the optical unit; wherein the optical unit comprises a slide (11) sliding along a linear guide system parallel to the translation axis;
at least a first magnetic actuator comprising a first electromagnetic stator integral with the body and a first magnetic piston constrained to the optical unit; wherein the first magnetic piston is housed in a first seat formed in the first electromagnetic stator and movable along a first axis of motion parallel to the translation axis of the optical unit.

2. The movement device of claim 1, comprising a second magnetic actuator, comprising a second electromagnetic stator integral with the body and a second magnetic piston constrained to the optical unit; wherein the second magnetic piston is housed in a second seat formed in the second electromagnetic stator and movable along a second axis of motion parallel to the translation axis of the optical unit.

3. The movement device of claim 2, wherein the first magnetic actuator and the second magnetic actuator are arranged symmetrically with respect to a plane of symmetry of the optical unit, orthogonal to a plane containing the first axis of motion of the first magnetic actuator and of the second axis of motion of the second magnetic actuator.

4. The movement device of claim 3, wherein the guide system comprises a first guide and a second guide, parallel to one another and symmetrical with respect to the plane of symmetry; and wherein the slide comprises a first shoe slidingly engaged in the first guide and a second shoe slidingly engaged in the second guide.

5. The movement device of claim 4, wherein at least one of said first shoe and second shoe is connected to the optical unit by an arm with notches adapted to allow flexional deformations of the arm in a direction connecting the centres of the first shoe and the second shoe.

6. The movement device of claim 1, wherein each magnetic piston has a cylindrical shape with an axis parallel to the direction of movement of the magnetic piston and with opposing magnetic poles aligned along the axis of the magnetic piston.

7. The movement device of claim 1, wherein each electromagnetic stator comprises a cylindrical wall defining a cavity, within which the respective magnetic piston is slidingly housed, and wherein the cylindrical wall of each electromagnetic stator is associated with at least a first electro-conductive coil surrounding the respective magnetic piston and coaxial thereto.

8. The movement device of claim 7, wherein the cylindrical wall of each electromagnetic stator is associated with a second electro-conductive coil surrounding the respective magnetic piston and coaxial thereto; wherein preferably the first electro-conductive coil and the second electro-conductive coil are connected to one another in series; and wherein preferably the first electro-conductive coil and the second electro-conductive coil of each magnetic actuator are wound and can be connected to a source of current, so as to generate two opposing electromagnetic fields, which cooperate with the two opposing magnetic poles of the respective magnetic piston.

9. The movement device of claim 8, wherein the electro-conductive coils of the first magnetic actuator and of the second magnetic actuator are connected to one another in series or in parallel to two poles connecting to an electrical power source.

10. The movement device of claim 8, wherein the cylindrical wall of each electromagnetic stator is made of a material with high magnetic permeability and surrounds the respective electromagnetic coil or coils associated therewith.

11. The movement device of claim 10, wherein each magnetic piston comprises a cylindrical body featuring the two opposing magnetic poles, and two opposing discs with high magnetic permeability associated with two opposing ends of the cylindrical body; and wherein the cylindrical wall of high magnetic permeability material and the two discs with high magnetic permeability form a magnetic circuit in the respective magnetic actuator.

12. The movement device of claim 2, wherein the first magnetic piston and the second magnetic piston are mechanically connected to the optical unit at two points located on the ends of a segment, the mid-point whereof coincides with the centre of mass of the optical unit.

13. The movement device of claim 1, comprising a position sensor, adapted to detect the relative position of the optical unit with respect to the body.

14. The movement device of claim 13, wherein the position sensor comprises an electromagnetic radiation emitter and a linear position detector, having a sensitive surface adapted to receive electromagnetic radiation emitted by the emitter; wherein the position detector is adapted to generate a signal that is a function of the position of a spot of electromagnetic radiation generated by the emitter on the sensitive surface of the position detector; wherein preferably the linear position detector is associated with a screen connected to the optical unit and adapted to screen external radiations; and wherein preferably the emitter is in integral with the optical unit, and wherein the position detector is integral with the body; and wherein the movement of the optical unit along the translation axis causes a movement of the spot of electromagnetic radiation on the sensitive surface of the position detector in a direction parallel to the direction of the translation axis.

15. The movement device of claim 13, wherein the electro-magnetic radiation emitter and the position detector are fixed with respect to one another and are integral with one of said body and said optical unit; the position sensor comprises a cylindrical lens, movable integrally with the other of said body and said optical unit, so that a relative movement between the optical unit and the body causes a relative movement between the cylindrical lens and the detector; wherein the cylindrical lens has an axis inclined with respect to the direction of translation of the optical unit; wherein the cylindrical lens has a transparent surface facing the emitter and the detector, and an opposing reflective surface, so that a beam of electromagnetic radiation emitted by the emitter passes through the cylindrical lens and is reflected towards the detector, forming a spot on the sensitive surface of the detector, the position of said spot being a function of the mutual position between the cylindrical lens and detector.

16. The movement device of claim 1, wherein each magnetic actuator comprises a system for dissipating the heat generated by the electro-conductive coils, preferably comprising one of: a thermic coupling between each electro-conductive coil and the respective cylindrical wall of the electromagnetic stator; or a circuit for the transfer of heat from the cylindrical wall of the electromagnetic stator to the body, or both.

17. The movement device of claim 1, wherein the optical unit comprises a sleeve in which the focusing lens is housed, the sleeve preferably being interchangeable; and wherein the sleeve is preferably fixed in a manner allowing it to be removed from the slide, for example by means of a threaded ring nut.

18. A laser head comprising a laser source and a movement device; wherein the movement device comprises
a body;
an optical unit, movable with respect to the body along a translation axis and adapted to house the focusing lens with the optical axis of the focusing lens parallel to the translation axis of the optical unit; wherein the optical unit comprises a slide sliding along a linear guide system parallel to the translation axis;
at least a first magnetic actuator comprising a first electromagnetic stator integral with the body and a first magnetic piston constrained to the optical unit; wherein the first magnetic piston is housed in a first seat formed in the first electromagnetic stator and movable along a first axis of motion parallel to the translation axis of the optical unit.

19. An item of equipment comprising a laser head according to claim 18, and a system for reciprocal movement between the laser beam and a piece to be worked on using the laser beam.

20. A linear magnetic actuator, comprising an electromagnetic stator with a cylindrical wall, defining a cavity, in which are arranged a first electro-conductive coil and a second electro-conductive coil, wherein said electro-conductive coils surround a magnetic piston slidingly housed in the first electro-conductive coil and in the second electro-conductive coil and coaxial thereto; wherein the first electro-conductive coil and the second electro-conductive coil are connected to one another in series and are wound in opposite directions, so as to generate two opposing electromagnetic fields, which cooperate with the two opposing magnetic poles of the respective magnetic piston.

21. The actuator of claim 20, wherein: the cylindrical wall of the electromagnetic stator is made from a material with high magnetic permeability; the magnetic piston comprises a cylindrical body featuring the two opposing magnetic poles, and two opposing discs with high magnetic permeability associated with two opposing ends of the cylindrical body;
and the cylindrical wall made of a material with high magnetic permeability and the two discs with high magnetic permeability form a magnetic circuit.
